(19) United States
(12) Patent Application Publication
(10) Pub. No.: US 2023/0198470 A1
(43) Pub. Date: Jun. 22, 2023

(54) POWER AMPLIFIER WITH LINEARIZATION

(71) Applicants: Stefano Pellerano, Beaverton, OR (US); Chuanzhao Yu, Phoenix, AZ (US); JongSeok Park, Hillsboro, OR (US); LiChung Tony Chang, Hillsboro, OR (US)

(72) Inventors: Stefano Pellerano, Beaverton, OR (US); Chuanzhao Yu, Phoenix, AZ (US); JongSeok Park, Hillsboro, OR (US); LiChung Tony Chang, Hillsboro, OR (US)

(21) Appl. No.: 17/556,846

(22) Filed: Dec. 20, 2021

(51) Int. Cl. H03F 1/02; H03F 3/24; H03F 3/195; H03F 3/60

(52) U.S. Cl. CPC H03F 1/0288; H03F 3/245; H03F 3/195; H03F 3/604; H03F 2200/451

(57) ABSTRACT

An amplifier, communication device and method of amplification are disclosed. An RF signal is amplified by a Doherty power amplifier (DPA). The DPA has a main amplifier with a Class-AB amplifier in parallel with a Class-C amplifier. When the RF signal power is smaller than 6 dB PBO, the Class-AB amplifier provides the main amplifier amplification; when the RF signal is between 6 dB PBO and 0 dB PBO, both the Class-AB and Class-C amplifiers provide the main amplifier amplification.

### TECHNICAL FIELD

Embodiments described herein pertain to power amplifiers. Some embodiments relate to linearization techniques for power amplifiers.

### BACKGROUND

The never-ending increasing demand for high-speed communications involves wireless devices exchanging data and control signals with other devices for a wide variety of applications, including digital audio and video. With different numbers and generations of devices and communication protocols, the signal and complexity has concomitantly increased. In many cases, signals to be transmitted are amplified by one or more amplifiers, including a power amplifier (PA). In particular, a baseband signal may be amplified by the PA before up-conversion to a radio frequency (RF) frequency for over-the-air transmission. Like many communication components, the design of the PA involves tradeoffs between power consumption, which may be a significant contributor to the overall power consumption of the wireless device, and efficiency.

### BRIEF DESCRIPTION OF THE DRAWINGS

FIG. 1 is an exemplary block diagram of a radio architecture, according to some embodiments described herein.

FIG. 2 illustrates exemplary front-end module circuitry, according to some embodiments described herein.

FIG. 3 illustrates exemplary radio IC circuitry, according to some embodiments described herein.

FIG. 4 illustrates an exemplary functional block diagram of baseband processing circuitry, according to some embodiments described herein.

FIG. 5 shows an exemplary station (STA) according to some embodiments described herein.

FIG. 6 shows an exemplary Doherty power amplifier, according to some embodiments described herein.

FIG. 7 shows an exemplary cascode transistor and output capacitance variation, according to some embodiments described herein.

FIG. 8 shows an exemplary cascode transistor and output capacitance variation, according to some embodiments described herein.

FIG. 9A shows an exemplary parallel power amplifier configuration, according to some embodiments described herein.

FIG. 9B shows an exemplary series power amplifier configuration, according to some embodiments described herein.

FIGS. 10A-10C show an exemplary stacked power amplifier, according to some embodiments described herein.

FIG. 11 shows an exemplary simulated performance of the stacked power amplifier of FIGS. 10A-10C, according to some embodiments described herein.

FIG. 12 shows an exemplary method of providing power amplification, according to some embodiments described herein.

### DETAILED DESCRIPTION

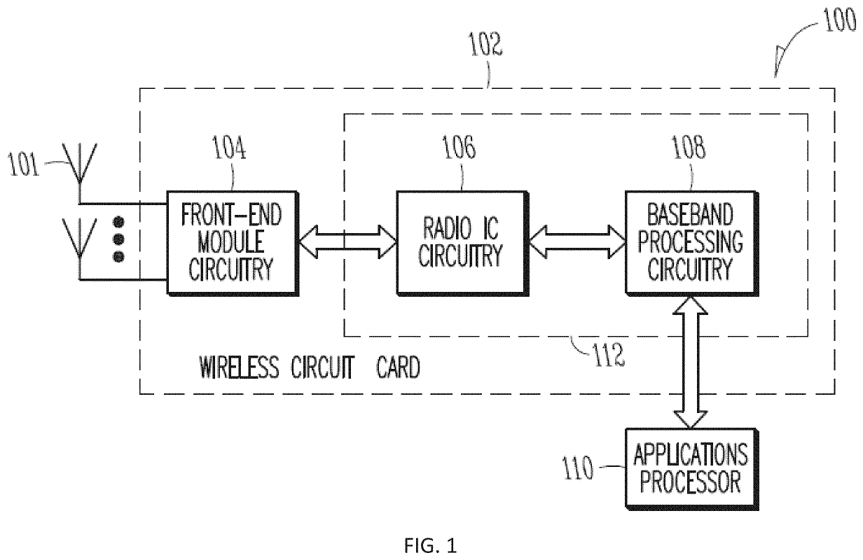

FIG. 1 is a block diagram of a radio architecture, according to some embodiments described herein. In some embodiments, some or all of the techniques or operations described herein may be applicable to the radio architecture 100 or other radio architectures. Some or all of the techniques described herein may be applicable to communication devices or other devices that may include a radio architecture such as 100 or other. However, the scope of embodiments is not limited in this respect, as some or all of the techniques or operations described herein may be applicable to other devices or architectures. In some embodiments, some or all of the techniques or operations described herein may be applicable to devices or architectures that may not necessarily be related to a radio architecture or communication device.

Referring to FIG. 1, the radio architecture 100 may include front-end module circuitry 104, radio IC circuitry 106 and baseband processing circuitry 108. Front-end module circuitry 104 may include a receive signal path which may include circuitry configured to operate on RF signals received from one or more antennas 101, amplify the received signals and provide the amplified versions of the received signals to the radio IC circuitry 106 for further processing. Front-end module circuitry 104 may also include a transmit signal path which may include circuitry configured to amplify signals for transmission provided by the radio IC circuitry 106 for transmission by one or more of the antennas 101.

Radio IC circuitry 106 may include a receive signal path which may include circuitry to down-convert RF signals received from the front-end module circuitry 104 and provide baseband signals to the baseband processing circuitry 108. Radio IC circuitry 106 may also include a transmit signal path which may include circuitry to up-convert baseband signals provided by the baseband processing circuitry 108 and provide RF output signals to the front-end module circuitry 104 for subsequent transmission.

Baseband processing circuitry 108 may include one or more processors and control logic to process the baseband signals received from the receive signal path of the radio IC circuitry 106 and to generate the baseband signals for the transmit signal path of the radio IC circuitry 106. Baseband processing circuitry 108 may interface with applications processor 110 for generation and processing of the baseband signals and for controlling operations of the radio IC circuitry 106.

In some embodiments, the antennas 101, the front-end module circuitry 104, the radio IC circuitry 106, and baseband processing circuitry 108 may be provided on a single circuit card, such as wireless circuit card 102, although the scope of the embodiments is not limited in this respect. In some other embodiments, the antennas 101, the front-end module circuitry 104 and the radio IC circuitry 106 may be provided on a single circuit card. In some embodiments, the radio IC circuitry 106 and the baseband processing circuitry 108 may be provided on a single chip or integrated circuit (IC), such as IC 112, although the scope of the embodiments is not limited in this respect.

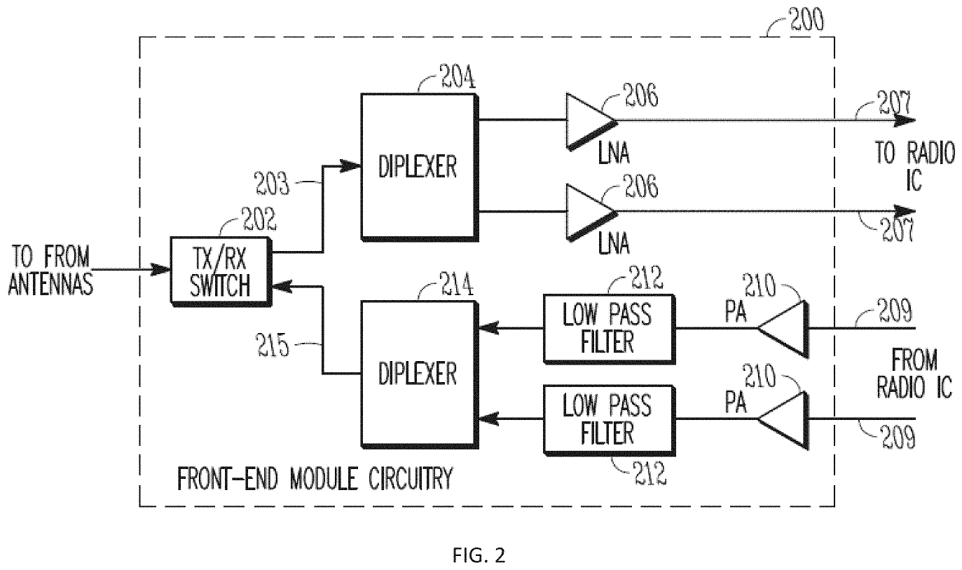

FIG. 2 illustrates front-end module circuitry, according to some embodiments described herein. The front-end module circuitry 200 is one example of circuitry that may be suitable for use as the front-end module circuitry 104 (FIG. 1), although other circuitry configurations may also be suitable. In some embodiments, the front-end module circuitry 200 may include a TX/RX switch 202 to switch between transmit mode and receive mode operation. The front-end module circuitry 200 may include a receive signal path and a transmit signal path. The receive signal path of the front-end module circuitry 200 may include a low-noise amplifier (LNA) 206 to amplify received RF signals 203 and provide the amplified received RF signals 207 as an output (e.g., to the radio IC circuitry 106 (FIG. 1)). The transmit signal path of the front-end module circuitry 200 may include one or more power amplifiers (PAs) 210 to amplify input RF signals 209 (e.g., provided by the radio IC circuitry 106), and one or more filters 212 to generate RE signals 215 for subsequent transmission (e.g., by one or more of the antennas 101 (FIG. 1)).

It should be noted that the front-end module circuitry 200 may include one or more additional components, in some embodiments. In addition, one or more components of the front-end module circuitry 200 may be arranged differently than shown in FIG. 2, in some embodiments.

In some embodiments, the front-end module circuitry 200 may be configured to operate in multiple frequency bands. As a non-limiting example, either the 2.4 GHz frequency spectrum or the 5 GHz frequency spectrum may be used. As another example, more than two frequency bands may be used. In these embodiments, the receive signal path of the front-end module circuitry 200 may include a receive signal path diplexer 204 to separate the signals from each spectrum as well as a separate LNA 206 for each spectrum. In these embodiments, the transmit signal path of the front-end module circuitry 200 may also include a power amplifier 210 and a filter 212 for each frequency spectrum and a transmit signal path diplexer 214 to provide the signals of one of the different spectrums onto a single transmit path for subsequent transmission by the one or more of the antennas 101 (FIG. 1). These embodiments are not limiting, however, as the front-end module circuitry 200 may be configured to operate in one frequency band, in some cases.

It should be noted that embodiments are not limited to PAs included in external front-end module circuitry. In some embodiments, one or more internal PAs integrated in silicon may be used. As a non-limiting example, one or more internal PAs may be integrated in silicon in other circuitry/components of a device, including but not limited to the radio architecture 100.

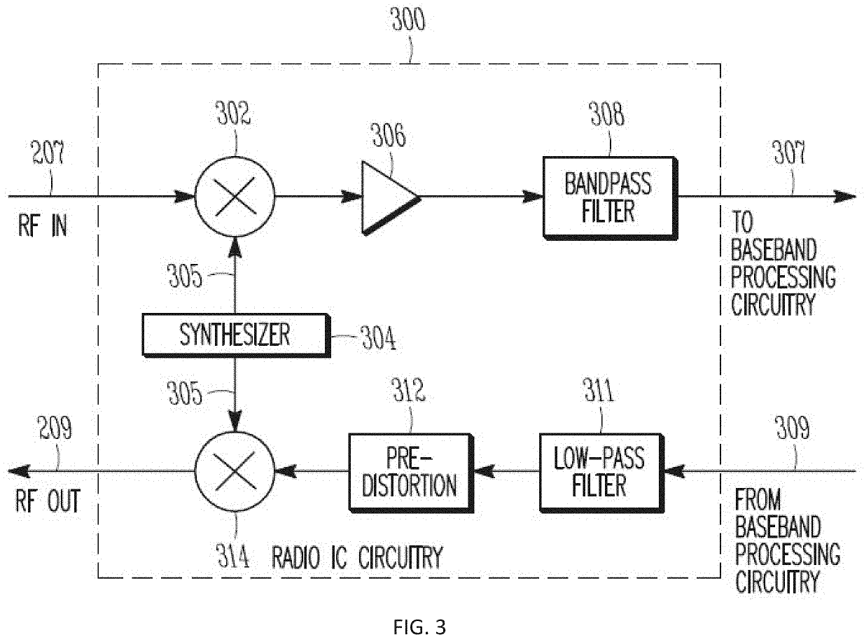

FIG. 3 illustrates radio IC circuitry, according to some embodiments described herein. The radio IC circuitry 300 is one example of circuitry that may be suitable for use as the radio IC circuitry 106 (FIG. 1), although other circuitry configurations may also be suitable. In some embodiments, radio IC circuitry may include one or more components shown in the example radio IC circuitry 300. In some embodiments, radio IC circuitry may include one or more additional components. In some embodiments, radio IC circuitry may not necessarily include all components shown in the example radio IC circuitry 300.

In some embodiments, the radio IC circuitry 300 may include a receive signal path and a transmit signal path. The receive signal path of the radio IC circuitry 300 may include at least mixer circuitry 302, amplifier circuitry 306 (such as the power amplifiers described below) and filter circuitry 308. The transmit signal path of the radio IC circuitry 300 may include at least one filter circuitry 311 and mixer circuitry 314. The transmit signal path may also include pre-distortion circuitry 312, in some embodiments. Radio IC circuitry 300 may also include synthesizer circuitry 304 for synthesizing a frequency 305 for use by the mixer circuitry 302 and/or the mixer circuitry 314.

In some embodiments, mixer circuitry 302 may be configured to down-convert RF signals 207 received from the front-end module circuitry 104 (FIG. 1) based on the synthesized frequency 305 provided by synthesizer circuitry 304. The amplifier circuitry 306 may be configured to amplify the down-converted signals and the filter circuitry 308 may be a band-pass filter (BPF) configured to remove unwanted signals from the down-converted signals to generate output baseband signals 307. Output baseband signals 307 may be provided to the baseband processing circuitry 108 (FIG. 1) for further processing. In some embodiments, the output baseband signals 307 may be zero-frequency baseband signals, although this is not a requirement. In some embodiments, mixer circuitry 302 may comprise passive mixers, although the scope of the embodiments is not limited in this respect.

In some embodiments, the mixer circuitry 314 may be configured to up-convert input baseband signals 309 based on the synthesized frequency 305 provided by the synthesizer circuitry 304 to generate RF output signals 209 for the front-end module circuitry 104. The baseband signals 309 may be provided by the baseband processing circuitry 108 and may be processed by one or more of the filter circuitry 311 and/or pre-distortion circuitry 312. The filter circuitry 311 may include a low-pass filter (LPF), although the scope of the embodiments is not limited in this respect.

In some embodiments, the output baseband signals 307 and the input baseband signals 309 may be analog baseband signals, although the scope of the embodiments is not limited in this respect. In some alternate embodiments, the output baseband signals 307 and the input baseband signals 309 may be digital baseband signals. In these alternate embodiments, the radio IC circuitry may include analog-to-digital converter (ADC) and digital-to-analog converter (DAC) circuitry. In some dual-mode embodiments, a separate radio IC circuitry may be provided for processing signals for each spectrum, although the scope of the embodiments is not limited in this respect.

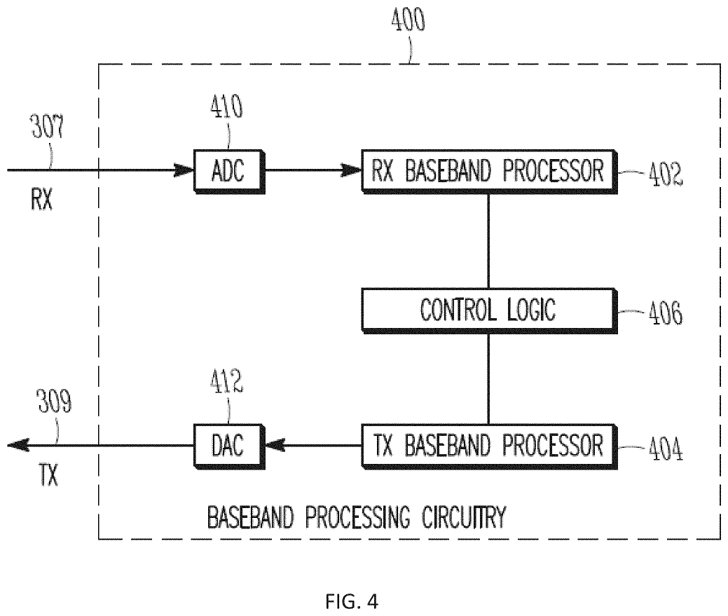

FIG. 4 illustrates a functional block diagram of baseband processing circuitry, according to some embodiments described herein. The baseband processing circuitry 400 is one example of circuitry that may be suitable for use as the baseband processing circuitry 108 (FIG. 1), although other circuitry configurations may also be suitable. The baseband processing circuitry 400 may include a receive baseband processor (RX BBP) 402 for processing receive baseband signals 307 provided by the radio IC circuitry 106 (FIG. 1) and a transmit baseband processor (TX BBP) 404 for generating transmit baseband signals 309 for the radio IC circuitry 106. The baseband processing circuitry 400 may also include control logic 406 for coordinating the operations with the baseband processing circuitry 400.

In some embodiments (e.g., when analog baseband signals are exchanged between the baseband processing circuitry 400 and the radio IC circuitry 106), the baseband processing circuitry 400 may include ADC 410 to convert analog baseband signals received from the radio IC circuitry 106 to digital baseband signals for processing by the RX BBP 402. In these embodiments, the baseband processing circuitry 400 may also include DAC 412 to convert digital baseband signals from the TX BBP 504 to analog baseband signals.

Referring to FIG. 1, in some embodiments, the antennas 101 (FIG. 1) may comprise one or more directional or omnidirectional antennas, including, for example, dipole antennas, monopole antennas, patch antennas, loop antennas, micro-strip antennas or other types of antennas suitable for transmission of RF signals. In some multiple-input multiple-output (MIMO) embodiments, the antennas may be effectively separated to take advantage of spatial diversity and the different channel characteristics that may result.

Although the radio-architecture 100 is illustrated as having several separate functional elements, one or more of the functional elements may be combined and may be implemented by combinations of software-configured elements, such as processing elements including digital signal processors (DSPs), and/or other hardware elements. For example, some elements may comprise one or more microprocessors, DSPs, field-programmable gate arrays (FPGAs), application specific integrated circuits (ASICs), radio-frequency integrated circuits (RFICs) and combinations of various hardware and logic circuitry for performing at least the functions described herein. In some embodiments, the functional elements may refer to one or more processes operating on one or more processing elements.

In some embodiments, the radio architecture 100 may be part of a communication device such as a wireless local area network (WLAN) communication station (STA), a wireless access point (AP), user equipment WE), an Evolved Node-B (eNB), a base station or a mobile device including a Wireless Fidelity (Wi-Fi) device. In some of these embodiments, radio architecture 100 may be configured to transmit and receive signals in accordance with specific communication standards, such as one or more Institute of Electrical and Electronics Engineers (IEEE) standards, including but not limited to various IEEE 802.11 standards. Such standards may include, but are not limited to IEEE 802.11-2012, 802.11n-2009, 802.11ac, and/or 802.11 ax standards and/or proposed specifications for WLANs. In some embodiments, radio architecture 100 may be configured to transmit and receive signals in accordance with Third Generation Partnership Project (3GPP) standards including Long Term Evolution (LTE) standards. The scope of the embodiments is not limited in this respect, however, as the radio architecture 100 may also be suitable to transmit and/or receive communications in accordance with other techniques and standards. In addition, the radio architecture 100 may be configured to transmit and receive signals in multiple frequency bands in some embodiments.

In some embodiments, the radio architecture 100 may be part of a communication device such as a personal digital assistant (PDA), a laptop or portable computer with wireless communication capability, a web tablet, a wireless telephone, a smart-phone, a wireless headset, a pager, an instant messaging device, a digital camera, an access point, a television, a wearable device such as a medical device (e.g., a heart rate monitor, a blood pressure monitor, etc.), or other device that may receive and/or transmit information wirelessly. In some embodiments, the communication device may include one or more of a keyboard, a display, a non-volatile memory port, multiple antennas, a graphics processor, an application processor, speakers, and other mobile device elements. The display may be an LCD screen including a touch screen

In some embodiments, the communication device may be or may be configured to operate as a mobile device and/or a stationary non-mobile device. As an example, the communication device may be an AP or an STA. In some embodiments, the communication device may also be, or may be part of, an apparatus for such a device. As an example, an STA may include the communication device in addition to other equipment, components or elements. As another example, an AP may include the communication device in addition to other equipment, components or elements. It should also be noted that some embodiments may be related to other electrical devices, electrical circuits or other devices that may or may not be related to communication.

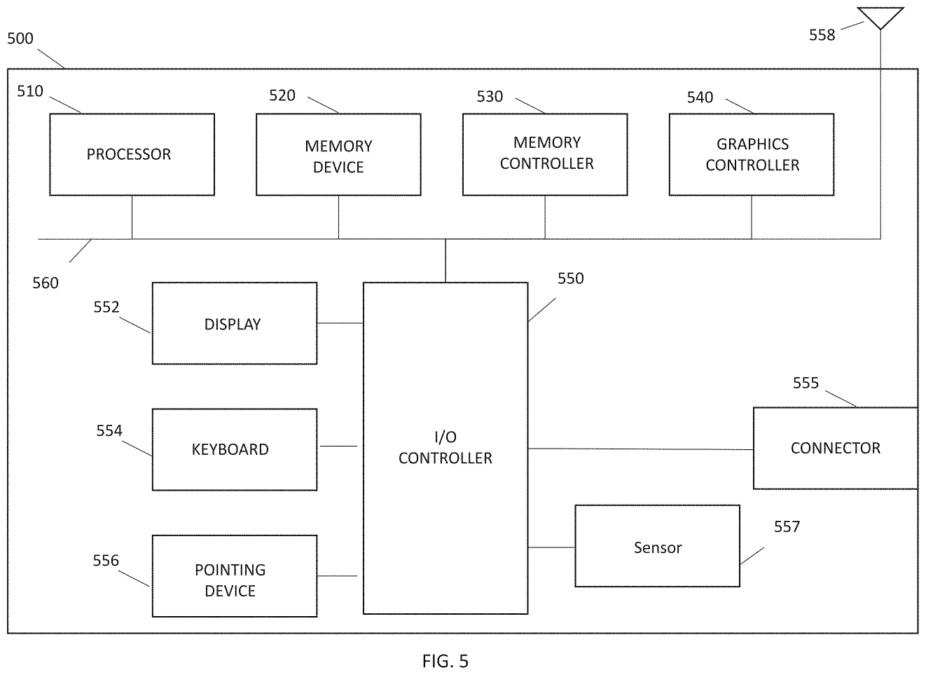

FIG. 5 shows a STA, according to some embodiments described herein. The STA 500 may be, for example, a mobile device such as a smartphone, a laptop computer, a tablet, or other electronic system. Examples, as described herein, may include, or may operate on, logic or a number of components, modules, or mechanisms. Modules and components are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” (and “component”) is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

As shown in FIG. 5, STA 500 may include components located on a circuit board (e.g., printed circuit board (PCB)) 502, such as a processor 510, a memory device 520, a memory controller 530, a graphics controller 540, an I/O controller 550, a display 552, a keyboard 554, a pointing device 556, at least one antenna 558, a connector 555, and a bus 560. Display 552 may include a liquid crystal display (LCD), a touchscreen (e.g., capacitive or resistive touchscreen), or another type of display. Pointing device 556 may include a mouse, a stylus, or another type of pointing device. Bus 560 may include conductive lines (e.g., metal-based traces on a circuit board where the components of STA 500 are located). The STA 500 may further include one or more sensors 557, such as a global positioning system (GPS) sensor, compass, accelerometer, or other sensor.

Processor 510 may include a general-purpose processor, an application specific integrated circuit (ASIC), or other kinds of processors. Processor 510 may include a CPU. Memory device 520 may include a dynamic random access memory (DRAM) device, a static random access memory (SRAM) device, a flash memory device, phase change memory, a combination of these memory devices, or other types of memory. FIG. 5 shows an example where memory device 520 is a stand-alone memory device separated from processor 510. In an alternative arrangement, memory device 520 and processor 510 may be located on the same die. In such an alternative arrangement, memory device 520 may be an embedded memory in processor 510, such as embedded DRAM (eDRAM), embedded SRAM (eSRAM), embedded flash memory, or another type of embedded memory. The memory device 520 may contain any or all of removable storage and non-removable storage, volatile memory or non-volatile memory.

I/O controller 550 may include a communication module for wired or wireless communication (e.g., communication through one or more antenna 558). Such wireless communication may include communication in accordance with WiFi communication technique, Long Term Evolution Advanced (LTE-A) communication technique, or other communication techniques. I/O controller 550 may also include a module to allow the STA 500 to communicate with other devices or systems in accordance with to one or more of the following standards or specifications (e.g., I/O standards or specifications), including Universal Serial Bus (USB), DisplayPort (DP), High-Definition Multimedia Interface (HDMI), Thunderbolt, Peripheral Component Interconnect Express (PCIe), Ethernet, and other specifications.

Connector 555 may be arranged (e.g., may include terminals, such as pins) to allow the STA 500 to be coupled to an external device (or system). This may allow the STA 500 to communicate (e.g., exchange information) with such a device (or system) through connector 555. Connector 555 and at least a portion of bus 560 may include conductive lines that conform with at least one of USB, DP, HDMI, Thunderbolt, PCIe, Ethernet, and other specifications.

As shown in FIG. 5, each of processor 510, memory device 520, memory controller 530, graphics controller 540, and I/O controller 550 may be present. However, fewer than all of processor 510, memory device 520, memory controller 530, graphics controller 540, and I/O controller 550 may be present.

FIG. 5 shows the components of the STA 500 arranged separately from each other as an example. For example, each of processor 510, memory device 520, memory controller 530, graphics controller 540, and I/O controller 550 may be located on a separate IC (e.g., semiconductor die or an IC chip). In some arrangements, two or more components (e.g., processor 510, memory device 520, graphics controller 540, and I/O controller 550) of the STA 500 may be located on the same die (e.g., same IC chip) that may be part of a system on chip, a system in a package, or other electronic devices or systems,

The illustrations described above are intended to provide a general understanding of the structure of different embodiments, and are not intended to provide a complete description of all the elements and features of an apparatus that might make use of the structures described herein. In some arrangements, STA 500 does not have to include a display. Thus, display 552 may be omitted from STA 500. In some arrangements, the STA 500 does not have to include any antenna. Thus, antenna 558 may be omitted from the STA 500. In some arrangements, the STA 500 does not have to include a connector. Thus, connector 555 may be omitted from the STA 500.

The memory device 520 may include a non-transitory machine readable medium (hereinafter simply referred to as machine readable medium) on which is stored one or more sets of data structures or instructions (e.g., software) embodying or utilized by any one or more of the techniques or functions described herein. The term “machine readable medium” may include a single medium or multiple media (e.g., a centralized or distributed database, and/or associated caches and servers) configured to store the one or more instructions. The term “machine readable medium” may include any medium that is capable of storing, encoding, or carrying instructions for execution by the STA 500 and that cause the STA 500 to perform any one or more of the techniques of the present disclosure, or that is capable of storing, encoding or carrying data structures used by or associated with such instructions. Non-limiting machine readable medium examples may include solid-state memories, and optical and magnetic media. Specific examples of machine readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks.

The instructions may further be transmitted or received over a communications network using a transmission medium utilizing any one of a number of wireless local area network (WLAN) transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks. Communications over the networks may include one or more different protocols, such as Institute of Electrical and Electronics Engineers (IEEE) 802.11 family of standards known as Wi-Fi, IEEE 802.16 family of standards known as WiMax, IEEE 802.15.4 family of standards, a Long Term Evolution (LTE) family of standards, a Universal Mobile Telecommunications System (UMTS) family of standards, peer-to-peer (P2P) networks, a next generation (NG)/5^{th} generation (5G) standards among others. In an example, the network interface device may include one or more physical jacks (e.g., Ethernet, coaxial, or phone jacks) or one or more antennas to connect to the transmission medium.

Note that the term “circuitry” as used herein refers to, is part of, or includes hardware components such as an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” or “processor” as used herein thus refers to, is part of, or includes circuitry capable of sequentially and automatically carrying out a sequence of arithmetic or logical operations, or recording, storing, and/or transferring digital data. The term “processor circuitry” or “processor” may refer to one or more application processors, one or more baseband processors, a physical central processing unit (CPU), a single- or multi-core processor, and/or any other device capable of executing or otherwise operating computer-executable instructions, such as program code, software modules, and/or functional processes.

In the detailed description and the claims, a list of items joined by the term “at least one of” may mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A may include a single element or multiple elements. Item B may include a single element or multiple elements. Item C may include a single element or multiple elements.

To increase the efficiency of spectrum use, various modulation schemes have been developed. One such digital modulation scheme, Quadrature Amplitude Modulation (QAM), is a combination of both amplitude and phase modulation techniques in which two carriers shifted in phase by 90 degrees are modulated and the resultant output includes both amplitude and phase variations. Modern wireless communication protocols such as IEEE 802.1 lac use 256 QAM, with IEEE 802.11ax use 1024 QAM. In such systems, a particular type of power amplifier—a Doherty power amplifier may be used to achieve back-off efficiency improvement.

The Doherty power amplifier combines two amplifiers, a main (carrier) amplifier and an auxiliary (peaking) amplifier. The main and auxiliary amplifiers are biased differently. The main amplifier is biased at Class AB or Class B that delivers power at any power level. The auxiliary amplifier is biased at Class C that only conducts over high power region. The Doherty amplifier improves the power added efficiency (PAE) compared to a normal power amplifier at backed off power levels.

During operation, the main amplifier is used to accommodate power levels around the average power level of the input signal; the auxiliary amplifier is biased that operation starts only when large peaks are present that the main amplifier would not be able to accommodate. Up to a 6 dB power backoff (PBO), the main amplifier operates with a load impedance of 2×R_{L}Ω, while the auxiliary amplifier is deactivated to achieve a peak efficiency at 6 dB PBO. The PBO is the power level below the saturation point at which the amplifier operates in the linear region even if there is a slight increase in the input power level; 6 dB PBO is thus 6 dB below the saturation point. From 6 dB PBO to 0 dB PBO, the auxiliary amplifier is activated and modulates the load impedance of the main amplifier (R_{L}Ω at 0 dB PBO) and the Doherty power amplifier achieves another peak efficiency at 0 dB PBO. Typically, the Class-AB main amplifier is designed (sized) to achieve a peak efficiency at 6 dB PBO with a load impedance of 2×R_{L} Ω.

The main amplifier of the Doherty power amplifier is designed to have a desired device size and bias point to achieve a high efficiency both with a load impedance of 2×R_{L} at 6 dB PBO and R_{L} at 0 dB PBO. However, as usual, a tradeoff exists between 6 dB PBO efficiency (load impedance of 2×R_{L}) and 0 dB PBO efficiency (load impedance of R_{L}) with the given device size of a Class-AB biased main power amplifier. For example, a Class-AB biased main amplifier size designed to achieve a high efficiency at 6 dB PBO with the load impedance of 2×R_{L} has a degraded efficiency at 0 dB PBO due to the load impedance modulation (R_{L} at 0 dB PBO) and corresponding driving capability. Furthermore, the linearity of the Doherty power amplifier is also degraded due to the load impedance modulation and driving capability of main amplifier.

In order to address these challenges, in some embodiments one or more Class-C biased power amplifiers may be provided as additional amplifiers in parallel with the Class-AB power amplifier in the main amplifier in addition to using one or more Class-C power amplifiers in the auxiliary amplifier. In this case, the Class-AB power amplifier in the main amplifier may be sized/optimized to achieve the highest efficiency with a load impedance of 2×R_{L} at 6 dB PBO and the added Class-C power amplifier may be sized/optimized to achieve the highest efficiency when used together with the parallel Class-AB power amplifier with a load impedance of R_{L} at 0 dB PBO. The additional Class-C power amplifier(s) in the main amplifier may improve the driving capability of the main amplifier in the Doherty power amplifier in the 6 dB PBO to 0 dB PBO region as well as improving the linearity of the Doherty power amplifier, thereby relaxing the tradeoff between 6 dB PBO efficiency and 0 dB PBO efficiency with device size.

The phase linearity of the power amplifier supports a spectrum efficient modulation scheme such as 256 QAM with a wide modulation bandwidth. The phase distortion of the power amplifier is often due to power amplifier output capacitance variations over power {power amplifier output device capacitance (C_{dev})} that modulates the phase response of the power amplifier output passive network (L-C network), resulting in amplitude modulation-phase modulation (AM-PM) distortion of the power amplifier. Therefore, to minimize the AM-PM distortion of the power amplifier, the power amplifier output device output capacitance variations may be reduced over power. The bias scheme and power amplifier topology described herein can compensate the power amplifier output device capacitance variation over power. The Doherty power amplifier may use one or more biasing circuits to bias the various amplifiers, as well as separate tuning inputs to tune cascode transistors of one or more of the amplifiers.

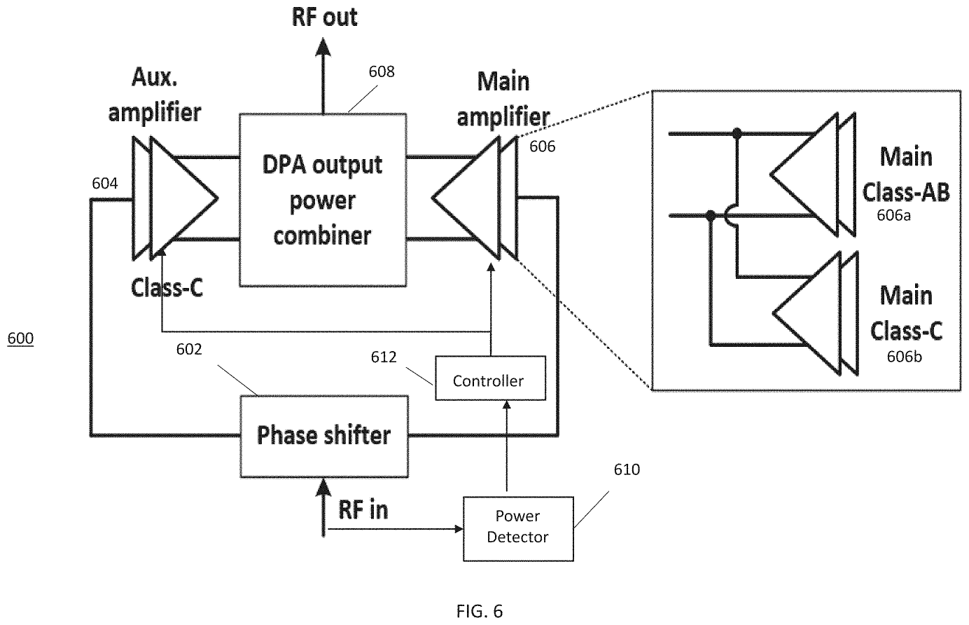

FIG. 6 shows a Doherty power amplifier, according to some embodiments described herein. Note that only some of the elements of the Doherty power amplifier 600 are shown in FIG. 6; specific elements such as output phase shifters and others are not shown for convenience. In the Doherty power amplifier 600, an input RF signal is split using a quadrature coupler (shown as a phase shifter 602 but also referred to as a splitter 602) so that the RF signal to the auxiliary amplifier 604 is 90 degrees out of phase with the RF signal supplied to the main amplifier 606 due to the use of inductive splitters to split the input RF signal. The RF signals from the main and auxiliary amplifiers 604, 606, which are 90 degrees (90°) out of phase, are provided to a passive network to be brought back into phase and reactively combined using a quarter-wave transmission line. The entire output structure is shown in FIG. 6 as the Doherty power amplifier power combiner 608. At this point the two signals in parallel create a Z₀/2 impedance, which may be increased to Z₀ by a quarter-wave transformer.

As above, the splitter 602 introduces a 90° phase shift on one leg. The Doherty power amplifier power combiner 608 may adjust the phase of the signals from at least one of the main and auxiliary amplifiers 604, 606 to compensate for (i.e., cancel) this phase shift. In addition, however, the main and auxiliary amplifiers 604, 606 may themselves introduce a phase shift. This amplifier phase shift may not be match as each of the main and auxiliary amplifiers 604, 606 is designed to handle different power levels. Moreover, it is desirable for the impedances and linearities of the main and auxiliary amplifiers 604, 606 to be maintained over the operating range, the latter of which may encounter distortion when the auxiliary amplifier 604 activates.

The main amplifier 606 contains at least two individual power amplifiers: a Class-AB power amplifier 606a in addition to a main Class-C power amplifier 606b, which may be independently activated and deactivated. The addition of the main Class-C power amplifier 606b enables the main amplifier 606 to provide the efficiency described above in the Doherty power amplifier 600. In particular, the Class-AB power amplifier 606a in the main amplifier 606 is sized/optimized to achieve the highest efficiency with a load impedance of 2×R_{L} at 6 dB PBO and the main Class-C power amplifier 606b is sized/optimized to achieve the highest efficiency together with the parallel Class-AB power amplifier 606a with a load impedance of R_{L} at 0 dB PBO.

In operation, the Class-AB power amplifier 606a operates with a load impedance of 2×R_{L} up to about 6 dB PBO. As used herein, about x dB includes up to about 0.1 dB. Since the Class-AB power amplifier 606a is optimized/sized with a load impedance of 2×R_{L}, the Class-AB power amplifier 606a achieves the highest first peak efficiency at 6 dB PBO. However, the main Class-C power amplifier 606b is deactivated up to about 6 dB PBO. A power detector 610 may be used to sense the voltage or power of the RF signal before the RF signal is applied to the splitter 602. In other embodiments, the power detector 610 may be used to detect the voltage or power of the RF signal between splitter 602 and the main amplifier 606. The power detector 610 may provide an indication to a controller 612, such as a processor, which may independently activate/deactivate the main Class-C power amplifier 606b and auxiliary amplifier 604, as well as control other aspects of the Doherty power amplifier 600 as indicated herein.

From about 6 dB PBO to about 0 dB PBO, with increasing input power, the auxiliary amplifier 604 (which is a Class-C power amplifier) starts delivering RF current and modulates the load impedance of the main amplifier 604. At the same time, the Class-C power amplifier 606b in main amplifier 606 starts delivering RF current to the load, enhancing driving capability of main amplifier 606 for the reduced load impedance. Together with the (Class-C power amplifier) auxiliary amplifier 604, and the Class-AB power amplifier 606a and the Class-C power amplifier 606b of the main amplifier 606 enhance a second peak efficiency at 0 dB PBO. Furthermore, the Class-C power amplifier 606b of main amplifier 606 provides an expansive gain response (positive third harmonic coefficient) and compensates a compressive gain response of the Class-AB power amplifier 606a (negative third harmonic coefficient), linearizing the overall gain response of the Doherty power amplifier 600 from about 6 dB PBO to about 0 dB PBO. For more precise control of turn on point of the auxiliary amplifier 604 and the Class-C power amplifier 606b of the main amplifier 606, adaptive bias techniques can be employed to further enhance the efficiency and linearity the Doherty power amplifier 600.

To support a spectrum-efficient modulation scheme such as 256 QAM with a wide modulation bandwidth, the phase linearity of the Doherty power amplifier 600 is considered. The phase distortion of a power amplifier is often due to output capacitance variations of the power amplifier over power {power amplifier output device capacitance (C_{dev})} that modulates the phase response of the power amplifier output passive network (L-C network), resulting in AM-PM distortion of the power amplifier. The power-dependent C_{dev} is mainly due to the C_{gd} variations of a cascode transistor over the operating region of the cascode transistor (saturation, triode, etc. due to the large voltage swing at the drain).

Adaptive bias techniques involve changing bias of the power amplifier dynamically (rather than using a fixed bias point) so that the turn on point can be more precisely controlled. One example of an adaptive bias technique may use a diode-connected NMOS in which the gate and drain terminal are connected together. The diode-connected NMOS may have a small DC current flowing into the drain terminal. The shorted drain/gate terminal may have a DC operation point close to the threshold voltage of the NMOS (Vₜₕ). Adaptive bias can be based on the Vₜₕ with a fixed DC value lower than Vₜₕ (i.e., Vₜₕ−ΔV) for a Class-C device, or a fixed DC value higher than Vₜₕ (i.e., Vₜₕ+ΔV) for a Class-AB device. A voltage adder or subtractor may be implemented by a summing amplifier or subtractor amplifier. The adaptive bias is to set a particular power amplifier (e.g., Class-AB or Class-C) constantly over process and temperature, which can vary Vₜₕ and may change the mode of the amplifier.

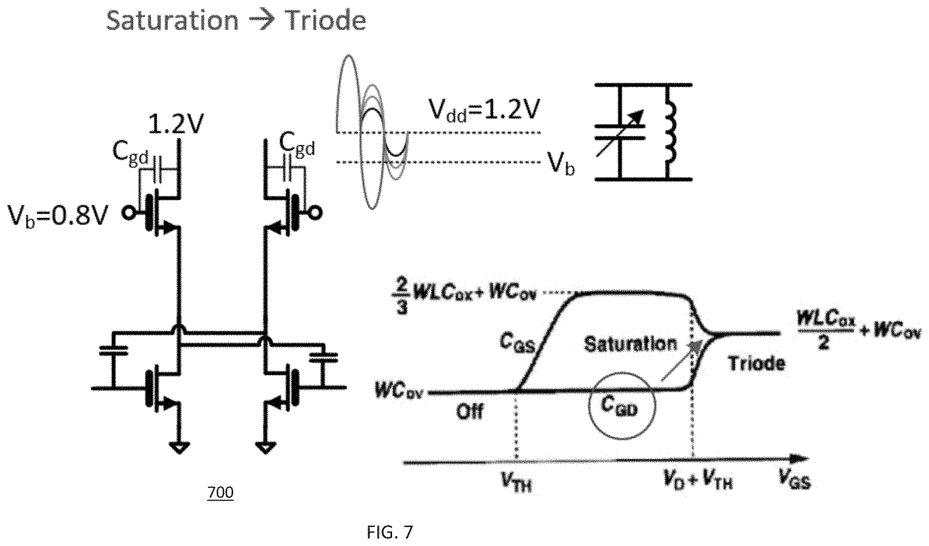

FIG. 7 shows a cascode transistor and output capacitance variation, according to some embodiments described herein. The cascode transistor 700 can form any of the amplifiers described above. In one embodiment, the cascode transistor 700 gate voltage is 0.8 V and the drain voltage is 1.2 V. The cascode transistor 700 is typically biased at the saturation region. In this case, with increasing voltage swing at the drain, the cascode transistor 700 operates in the triode region (the operating region in which the inversion region exists and current flows but the inversion region has begun to taper near the source; or the drain voltage is less than the gate voltage) for more fraction of the time. This increases the average C_{gd} capacitance with power, as shown by the arrow in FIG. 7. FIG. 7 thus shows the output capacitance variation as the cascode transistor 700 enters the triode region from the saturation region. The drain voltage swing of the cascode transistor 700 can be as large as 2×V_{dd} for the power amplifier, causing the output capacitance variation shown. As shown in FIG. 7, the power-dependent C_{gd} capacitance variation modulates the output passive network that follows the power amplifier, resulting in AM-PM distortion of the power amplifier output. Therefore, to minimize AM-PM distortion of the power amplifier, it is desirable to reduce the output device output capacitance variation over power for the power amplifier.

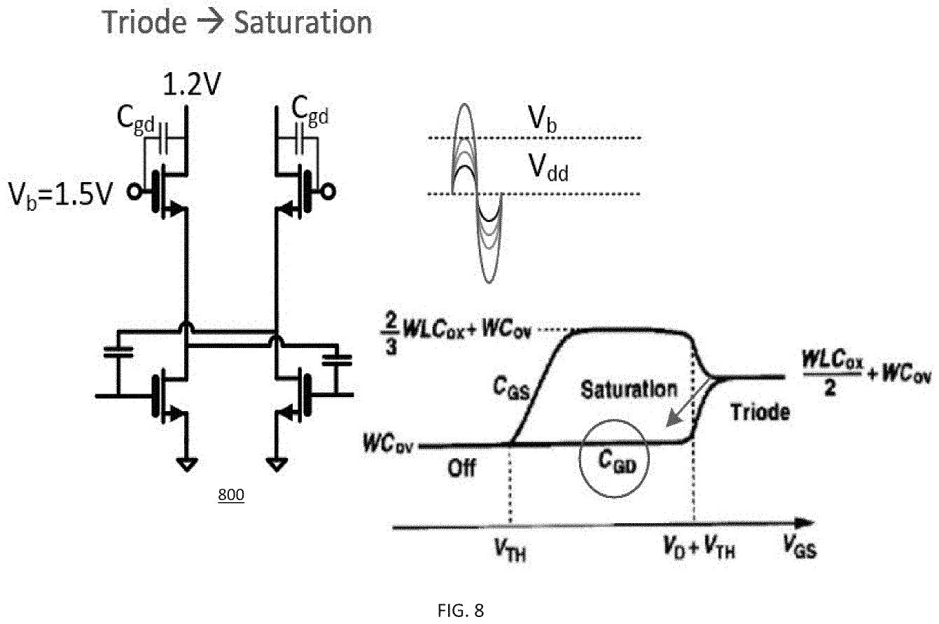

FIG. 8 shows a cascode transistor and output capacitance variation, according to some embodiments described herein. A bias scheme is used in FIG. 8 to compensate for the C_{gd} variation when the Class-C power amplifier is added either in parallel (parallel power amplifier) or in series (driver stage). In operation, the cascode transistor 800 is biased at the triode region (V_{b}=1.5V and V_{dd}=1.2V shown in FIG. 8) such that with increasing voltage swing at the drain, the cascode transistor operates in the saturation region for a greater fraction of the time than when the 0.8 V bias of FIG. 7 is provided. The average C_{gd} capacitance with power thus decreases, as shown by the arrow in FIG. 8. FIG. 8 thus shows the output capacitance variation as the cascode transistor 800 enters the saturation region from the triode region.

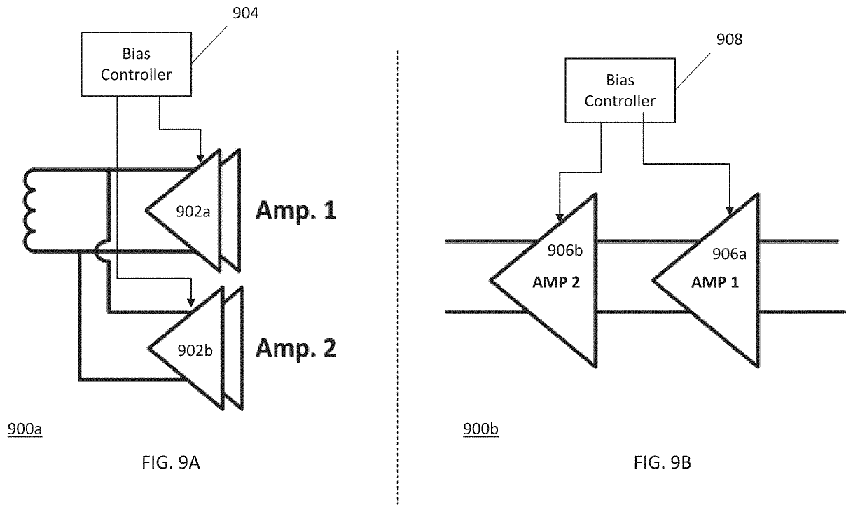

FIG. 9A shows a parallel power amplifier configuration, according to some embodiments described herein. FIG. 9B shows a series power amplifier configuration, according to some embodiments described herein. In the power amplifier configuration 900a of FIG. 9A, the biasing of the parallel amplifiers 902a, 902b is independently controlled by a first bias controller 904; while in the power amplifier configuration 900b of FIG. 9B, the biasing of the serial amplifiers 906a, 906b is independently controlled by a second bias controller 908. This allows the biasing of the amplifiers to be different, e.g., the biasing of one of the parallel amplifiers 902a, 902b to be in the saturation region and the other of the parallel amplifiers 902a, 902b to be set in the triode region, although these values may be adjusted as determined by the transistors and other devices in the parallel amplifiers 902a, 902b. Similarly, the biasing of the first serial amplifier 906a may be set at a higher voltage (so that the first serial amplifier 906a is nominally in triode region) than the second serial amplifier 906b (so that the second serial amplifier 906b is nominally in saturation region). Although voltages are provided in FIGS. 7 and 8, these biases are merely examples and may be adjusted as desired (and in some cases, the biasing of the first serial amplifier 906a may be set at a lower voltage than the second serial amplifier 906b). Although not shown, capacitors to ground may be present at the output of each of the parallel amplifiers 902a, 902b of FIG. 9A and the serial amplifiers 906a, 906b of FIG. 9B. Therefore, with the bias scheme, the power amplifier output device capacitance exhibits opposite characteristics over power (as the drain voltage changes); the first serial amplifier 906a enters the saturation region from the triode region as shown in FIG. 8 and the C_{gd} capacitance decreases, while the second serial amplifier 906b enters the triode region from the saturation region as shown in FIG. 7 and the C_{gd} capacitance increases.

The output capacitance can thus be averaged (either using the parallel scheme shown in FIG. 9A or the serial scheme shown in FIG. 9B) to enable a substantially constant C_{gd} capacitance and/or a substantially flat phase response to be obtained dependent on the design of the various amplifiers and biases. A substantially constant C_{gd} capacitance may be, for example, within about 1/10 or 1/20 of the nominal C_{gd} capacitance; substantially flat phase response may be, for example, within a few tenths of a dB (such as up to about 0.2 dB). The desired biasing for each amplifier in FIGS. 9A and 9B can be determined based on testing (e.g., determination of the second and third order harmonic effects on linearity) and may be stored in a processor (such as that shown in FIG. 5) for automatic adjustment. In this case, when the bias scheme is used (with the power amplifier either in a parallel or series configuration), the bias scheme can effectively increase the linearity and reduce the AM-PM distortion of the power amplifier. In addition, the size and bias point of the cascode transistor may be determined to modify the phase response over power such that the phase response of the overall power amplifier is linearized. Although only two amplifiers are shown in FIGS. 9A and 9B, any desired number of amplifiers can be used at different biases to provide the desired linearity (albeit at the cost of power consumption).

In addition to linearity, it is desirable to increase the power amplifier reliability. One power amplifier arrangement to increase reliability is to stack power amplifiers, however distortion of the stacked stage degrades the linearity performance. High DC current in the transconductance (gm) stage to boost the gain and linearity increases the static and dynamic currents in the stacked stages. The differences at the stack stage NMOS gate, source, and drain terminals introduces the non-linearity of the NMOS transconductance and capacitances, which degrades the power amplifier linearity.

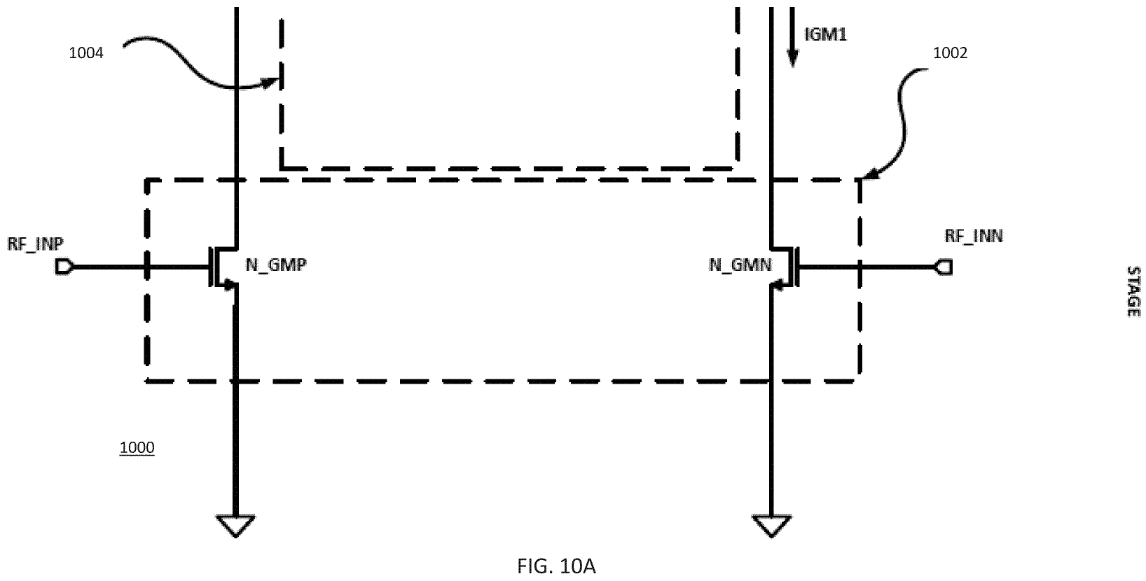

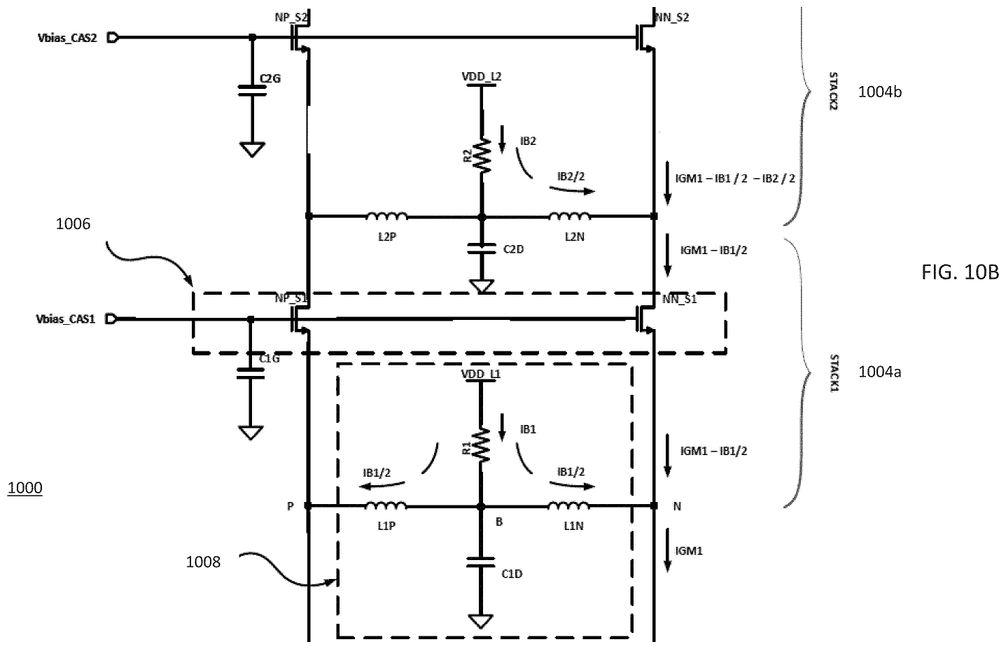

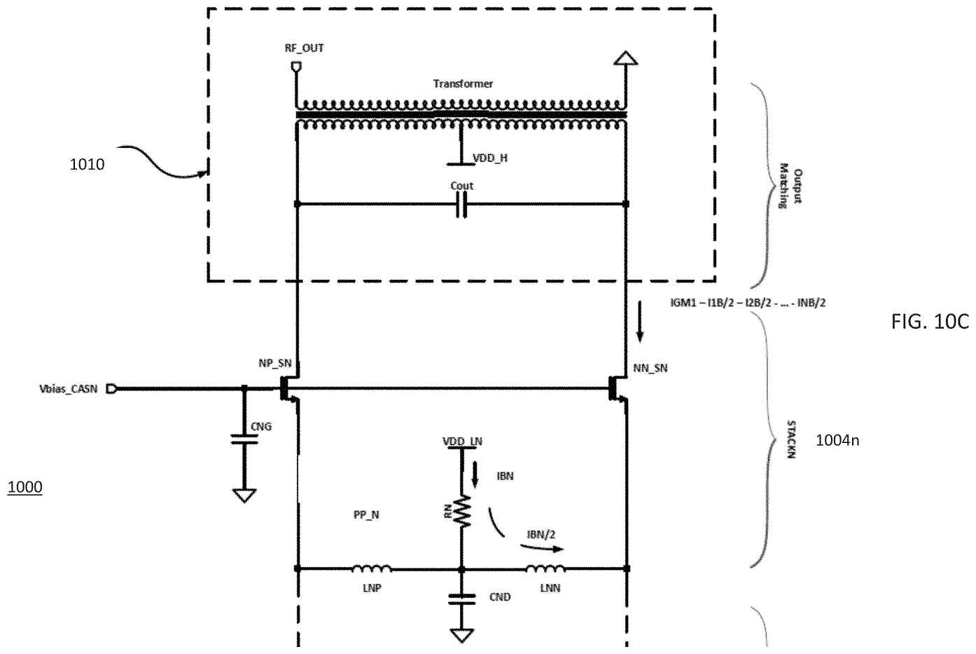

FIGS. 10A-10C show a stacked power amplifier, according to some embodiments described herein. In particular, FIG. 10A shows a first portion of the stacked power amplifier 1000; FIG. 10B shows a second portion of the stacked power amplifier 1000; and FIG. 10C shows a third portion of the stacked power amplifier 1000.

As shown in FIG. 10A, the first portion of the stacked power amplifier 1000 includes a gₘ stage 1002 and the relationship between the gₘ stage 1002 and the stacked amplifier stages 1004. The RF input of the stacked power amplifier 1000, which contains the RF and envelope current, is supplied to transistors of the gₘ stage 1002. The gₘ stage 1002 transfers the input voltage mode differential signals supplied to transistors of the gₘ stage 1002 to current mode differential signals with transconductance gain gₘ.

As shown in FIG. 10B, the second portion of the stacked power amplifier 1000 includes first and second amplifier stages 1004a, 1004b of the stacked amplifier stages 1004. Each of the amplifier stages 1004a, 1004b, . . . 704n of the stacked amplifier stages 1004 contains a cascade transistor pair 1006 that may, in some embodiments, be formed using NMOS transistors. A bias voltage is applied to the control terminal (e.g., gate) of each of the transistors of the cascade transistor pair 1006. The first amplifier stage 1004a conducts the current mode signal from the output of the gₘ stage 1002 and provides the current mode signal to the outputs of first stacked stage 1004a—the drain terminals of the NMOS transistors (first NMOS transistor NP_S1 and second NMOS transistor NN_S1) shown in FIG. 10B. The cascade transistor pair 1006 may act as a current buffer. Each of the amplifier stages 1004a, 1004b, . . . 704n of the stacked amplifier stages 1004 also contains a shunt network 1008.

Each shunt network 1008 includes a low pass filtering inductor that is resonant with a parasitic capacitance (the capacitance between the source and drain) for each stacked NMOS source terminal input. The shunt network 1008 of each amplifier stage 1004a, 1004b, . . . 704n contains a resistor (Rn), two identical inductors (first inductor LnP and second inductor LnN), and a decoupling capacitor (CnD) coupled to ground. The first inductor LnP is coupled between node B, which is between resistor Rn and decoupling capacitor CnD, and node P, which is between the drain of the NMOS transistor NP_Sn of the amplifier stage 1004n and the source of the NMOS transistor NP_Sn+1 of the next amplifier stage 1004n+1. Similarly, the second inductor LnN is coupled between node B, and node N, which is between the drain of the NMOS transistor NN_Sn of the amplifier stage 1004n and the source of the NMOS transistor NN_Sn+1 of the next amplifier stage 1004n+1. Thus, as shown in FIG. 10B, for the first amplifier stage 1004a, the first inductor L1P is coupled between node B, which is between resistor R1 and decoupling capacitor C1D, and node P, which is between the drain of the NMOS transistor NP_S1 of the first amplifier stage 1004a and the source of the NMOS transistor NP_S2 of the second amplifier stage 1004b; the second inductor L2N is coupled between node B, and node N, which is between the drain of the NMOS transistor NN_S1 of the amplifier stage 1004a and the source of the NMOS transistor NN_S2 of the next amplifier stage 1004b.

For the first amplifier stage 1004a, the parasitic capacitance looking into node P from the inductor L1P is Cpar. The inductor L1P resonates with Cpar at the RF frequency (ω) and is selected using:

$${L}_{1 P} = \frac{1}{{ω}^{2} {C}_{par}}$$

This permits the DC current to pass through the inductor L1P. The RF signal in current mode has a relatively high impedance formed by the parasitic capacitance Cpar and the inductor L1P. The current loss that is caused by the parasitic capacitance (Cpar, which resonates with L1P) is thus reduced. The DC voltage of node P is about (Vbias_{CAS1}−Vth). The DC current IB1 is determined by the supply voltage VDD_L1 and the DC voltage of node P:

$$IB 1 = \frac{{V DD}_{L 1} - ( {V bias}_{CAS 1} - V th )}{R 1}$$

That is VDD_L1 is higher than the voltage at node P, so that current flows to the drain of the gₘ stage 1002 transistor coupled to transistor NP_S1. This allows the shunt of the DC current flowing through the amplifier stages to be controlled and provides a lower overall power consumption by reducing the current draw from voltage VDD_H supplied by the output matching stage 1010 shown in FIG. 10C (e.g., if the gₘ transistor bias current is 100 mA and the NP_S1 transistor bias current is 80 mA, the current through the inductor L1P is 20 mA). Thus, this allows design of the DC current through transistor NP_S1 to increase the impendence and decrease the RF signal linearity with lower DC current. The resistor R1 may be selected to be a small value, and the supply voltage VDD_{L1} may be selected to be close to (Vbias_{CAS1}−Vth) to improve the power consumption of the first amplifier stage 1004a. A similar analysis may be used for each of the other amplifier stages, each of which may also contain a shunt network 1008. Thus, the supply voltage VDD_Ln of each amplifier stage may progressively increase to enable the current to flow from the supply voltage VDD_Ln to the lower amplifier stage (closer to the gₘ stage 1002). The values of the shunt network 1008 (i.e., Rn, CnD, LnP, LnN for amplifier stage n) in each amplifier stage may be selected for that amplifier stage and thus may be independent of the values for the other amplifier stages, so long as the shunt network 1008 acts for each amplifier stage as the fundamental AC signal blocker of the AC current so that the AC current passes between amplifier stages (i.e., as above the parasitic capacitance Cpar of the transistor and the inductor L1P/LIN resonate at the RF signal frequency). In other embodiments, one or more of the values of the shunt network 1008, such as CnD may be the same for all shunt networks. In various embodiments, the number of amplifier stages may be dependent on the amplifier design, but at least one amplifier stage may be present in addition to the gₘ stage 1002.

The input terminal of the first amplifier stage 1004a at the positive side is node P; the input terminal at the negative side of the first amplifier stage 1004a is node N. The RF current flows into the source terminal of NMOS FET—NP_S1 and NN_S1. The input impedance of NP_S1 or NN_S1 is

$$\frac{1}{{g}_{m}} ,$$

which can be relatively small. The gₘ is the transconductance of NP_S1 or NN_S1.

As shown in FIG. 10C, the third portion of the stacked power amplifier 1000 includes nth (last) amplifier stage 1004n of the stacked amplifier stages 1004 and the output matching stage 1010 coupled to the nth stacked amplifier stage 1004n. The shunt network 1008 thus boosts the fundamental input signals, lowers signal swings at low frequency (envelope) to provide better linearity for the stacked power amplifier 1000, and reduce a DC current from a higher VDD when the DC current is provided from a lower supply to improve the efficiency.

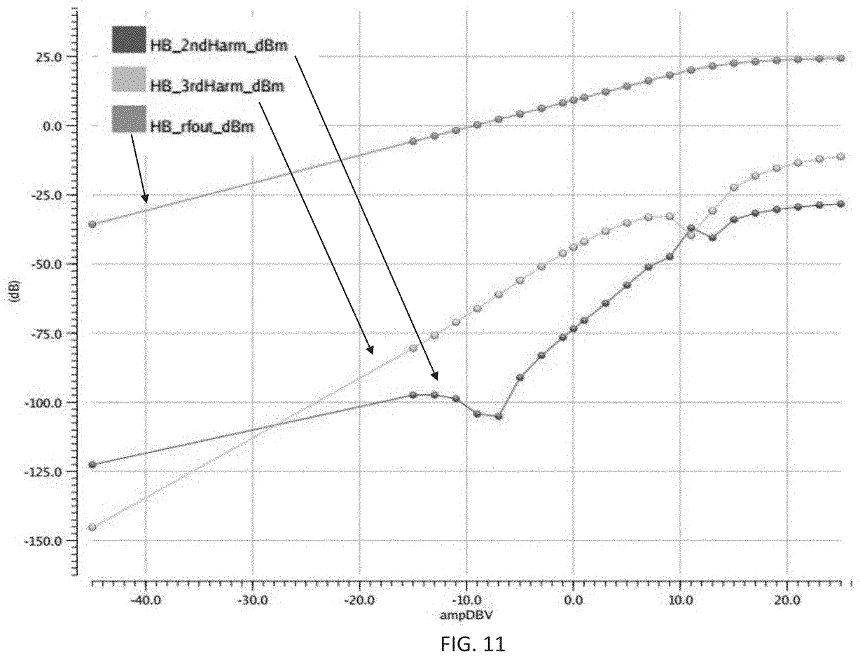

FIG. 11 shows simulated performance of the stacked power amplifier of FIGS. 10A-10C, according to some embodiments described herein. In particular, FIG. 11 shows the simulated fundamental, 2^{nd} harmonic, and 3^{rd} harmonic performances in dBm versus the input signal in dBV for the stacked power amplifier 1000. The simulation is based on the harmonic balance method, which is used to approximate periodic steady state solutions of transient partial differential equations in the frequency domain by incorporating the time dimension as part of a finite element scheme by resolving the temporal dimension with periodic sine and cosine functions at each spatial node. The stacked power amplifier of FIG. 11 was simulated with two amplifier stages. As shown, the output power with 1 dB compression (OP1DB) performance is 22 dBm with 50 ohm of load.

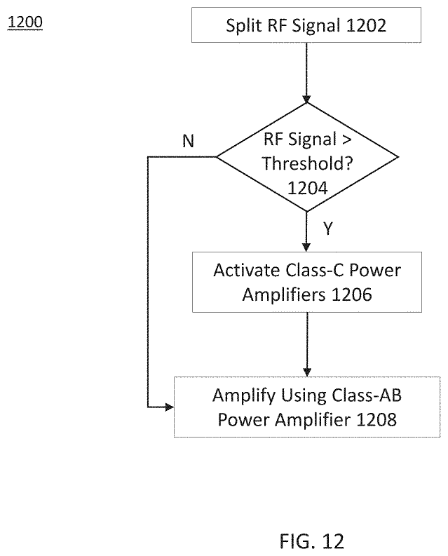

FIG. 12 shows a method of providing power amplification, according to some embodiments described herein. The method 1200 may be performed by a STA shown and described in the above figures. Embodiments of the method 1200 may include additional or fewer operations or processes in comparison to what is illustrated in FIG. 12. In addition, embodiments of the method 1200 are not necessarily limited to the chronological order that is shown in FIG. 12.

At operation 1202, an RF signal to be amplified by a power amplifier is split along two paths. The split RF signal is provided to a main amplifier that includes a Class-AB amplifier and a Class-C amplifier in parallel with the Class-AB amplifier on one of the paths, and an auxiliary power amplifier that includes Class-C amplifier along the other of the paths.

At operation 1204, the power of the RF signal is determined. That is, a power detector may determine whether the RF signal is greater than a predetermined threshold. The threshold may be, for example, 6 dB PBO for the Class-AB amplifier.

If it is determined at operation 1204 that the power of the RF signal is not greater than the threshold, a controller selects the amplification of the power amplifier so that the RF signal is only amplified by the Class-AB amplifier at operation 1208.

If it is determined at operation 1204 that the power of the RF signal is greater than the threshold, the controller activates the Class-C amplifier of the main amplifier and the auxiliary amplifier at operation 1206 in addition to the Class-AB amplifier at operation 1208. The amplified signals from the main amplifier and the auxiliary amplifier are then combined. Thus, the amplification of the power amplifier is a combination of all three amplifiers when the RF signal is greater than the threshold.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

The Abstract is submitted with the understanding that it will not be used to limit or interpret the scope or meaning of the claims. The following claims are hereby incorporated into the detailed description, with each claim standing on its own as a separate embodiment.

What is claimed is:

1. A Doherty power amplifier comprising:
a splitter to which a radio frequency (RF) signal is supplied, the splitter configured to provide a first and second path for the RF signal and introduce a phase shift along at least one of the first or second path;
a main amplifier coupled to the splitter via the first path, the main amplifier including a Class-AB amplifier and a main Class-C amplifier;
an auxiliary amplifier coupled to the splitter via the second path, the auxiliary amplifier including an auxiliary Class-C amplifier; and
a combiner configured to combine outputs of the main amplifier and the auxiliary amplifier and adjust the phase of the output from at least one of the main or auxiliary amplifiers to cancel the phase shift introduced by the splitter.

2. The Doherty power amplifier of claim 1, wherein the Class-AB amplifier and the main Class-C amplifier are connected in parallel.

3. The Doherty power amplifier of claim 1, wherein the Class-AB amplifier and the main Class-C amplifier are independently activatable.

4. The Doherty power amplifier of claim 3, wherein:
the Class-AB amplifier is configured to be activate up to about 0 dB power backoff (PBO), and
the main Class-C amplifier is configured to be activate between about 6 dB PBO and about 0 dB PBO and inactive below about 6 dB PBO.

5. The Doherty power amplifier of claim 4, wherein:
the main amplifier is configured to have a maximum efficiency with a load impedance of 2×R_{L} up to a power backoff of about 6 dB PBO, and
the main amplifier is configured to have a maximum efficiency with a load impedance of R_{L} between about 6 dB PBO and about 0 dB PBO.

6. The Doherty power amplifier of claim 4, wherein:
the auxiliary amplifier is configured to be activate between about 6 dB PBO and about 0 dB PBO and inactive below about 6 dB PBO, and
the auxiliary amplifier is configured to modulate a load impedance of the main amplifier between about 6 dB PBO and about 0 dB PBO.

7. The Doherty power amplifier of claim 1, wherein at least one of the Class-AB amplifier, the main Class-C amplifier, or the auxiliary amplifier comprises a plurality of biased amplifiers configured to be biased at voltages such that a first biased amplifier of the plurality of biased amplifiers transitions from saturation mode to triode mode while a second biased amplifier of the plurality of biased amplifiers transitions from the triode mode to the saturation mode with voltage swing.

8. The Doherty power amplifier of claim 7, wherein the first and second biased amplifiers are disposed in parallel such that inputs of the first and second biased amplifiers are coupled together and outputs of the first and second biased amplifiers are coupled together.

9. The Doherty power amplifier of claim 7, wherein the first and second biased amplifiers are disposed in serial such that an input of the second biased amplifier is coupled to an output of the first biased amplifier.

10. The Doherty power amplifier of claim 7, further comprising a bias controller configured to control biasing of the first and second biased amplifiers to provide a substantially flat phase response.

11. The Doherty power amplifier of claim 10, wherein the bias controller is configured to control biasing of the first and second biased amplifiers to provide an average gate-drain capacitance of the first and second biased amplifiers that remains substantially constant as the first biased amplifier transitions from the saturation mode to the triode mode and the second biased amplifier transitions from the triode mode to the saturation mode.

12. The Doherty power amplifier of claim 10, wherein the first and second biased amplifiers comprise cascode transistors, the bias controller configured to apply voltages to gates of a plurality of MOSFETs of the cascode transistors.

13. The Doherty power amplifier of claim 1, wherein at least one of the Class-AB amplifier, the main Class-C amplifier, or the auxiliary amplifier comprises a stacked power amplifier that includes:
a gₘ stage configured to receive an RF input voltage mode differential signal supplied to transistors of the gₘ stage to current mode differential signals with transconductance gain gₘ,
an output matching stage configured to match an impedance of an output of the stacked power amplifier with circuitry connected to the stacked power amplifier, and
a first stacked amplifier stage comprising:
a first cascade transistor pair coupled between the gₘ stage and the output matching stage, the first cascade transistor pair having control terminals configured to receive a first bias voltage, and
a first shunt network coupled between the first cascade transistor pair, the first shunt network configured to block a fundamental frequency of the RF input voltage mode differential signal and provide a direct current to the transistors of the gₘ stage.

14. The Doherty power amplifier of claim 13, wherein the shunt network comprises:
a first resistor coupled to a power supply,
a first capacitor coupled to the first resistor and to ground,
a first inductor coupled between a first node between the first resistor and capacitor and a second node between a first transistor of the first cascade transistor pair and a first transistor of the gₘ stage, and
a second inductor coupled between the first node and a third node between a second transistor of the first cascade transistor pair and a second transistor of the gₘ stage.

15. The Doherty power amplifier of claim 14, wherein a first resonant frequency of a first parasitic capacitance of the first transistor of the cascade transistor pair and the first inductor and a second resonant frequency of a second parasitic capacitance of the second transistor of the first cascade transistor pair and the second inductor is the fundamental frequency of the RF input voltage mode differential signal.

16. The Doherty power amplifier of claim 14, wherein:
a voltage provided by the power supply is higher than a voltage of the second or third node, and
a voltage provided by an output power supply of the output matching stage is higher than the voltage provided by the power supply.

17. The Doherty power amplifier of claim 13, further comprising a second stacked amplifier stage that includes:
a second cascade transistor pair coupled between the first stacked amplifier stage and the output matching stage, the second cascade transistor pair having control terminals configured to receive a second bias voltage, and
a second shunt network coupled between the second cascade transistor pair, the second shunt network configured to block the fundamental frequency of the RF input voltage mode differential signal and provide a direct current to transistors of the first cascade transistor pair.

18. The Doherty power amplifier of claim 17, wherein:
the first shunt network comprises:
a first resistor coupled to a first power supply,
a first capacitor coupled to the first resistor and to ground,
a first inductor coupled between a first node between the first resistor and first capacitor and a second node between a first transistor of the first cascade transistor pair and a first transistor of the gₘ stage, and
a second inductor coupled between the first node and a third node between a second transistor of the first cascade transistor pair and a second transistor of the gₘ stage, and
the second shunt network comprises:
a second resistor coupled to a second power supply,
a second capacitor coupled to the second resistor and to ground,
a third inductor coupled between a fourth node between the second resistor and second capacitor and a fifth node between a first transistor of the second cascade transistor pair and the first transistor of the first cascade transistor pair, and
a fourth inductor coupled between the fourth node and a sixth node between a second transistor of the second cascade transistor pair and the second transistor of the first cascade transistor pair.

19. The Doherty power amplifier of claim 18, wherein the fundamental frequency of the RF input voltage mode differential signal is each of:
a first resonant frequency of a first parasitic capacitance of the first transistor of the first cascade transistor pair and the first inductor,
a second resonant frequency of a second parasitic capacitance of the second transistor of the first cascade transistor pair and the second inductor,
a third resonant frequency of a third parasitic capacitance of the first transistor of the second cascade transistor pair and the third inductor, and
a fourth resonant frequency of a fourth parasitic capacitance of the second transistor of the second cascade transistor pair and the fourth inductor.

20. The Doherty power amplifier of claim 19, wherein:
a first voltage provided by the first power supply is higher than a voltage of the second or third node,
a second voltage provided by the second power supply is higher than a voltage of the third or fourth node,
the second voltage is higher than the first voltage, and
a voltage provided by an output power supply of the output matching stage is higher than the first or second voltage.

21. A method of detecting a proximate object, the method comprising:
splitting a radio frequency (RF) signal to be power amplified by a Doherty power amplifier into a first RF signal on a first path and a second RF signal on a second path, the Doherty power amplifier containing a main amplifier on the first path and an auxiliary amplifier on the second path, the main amplifier having a Class-AB amplifier in parallel with a Class-C amplifier;
determining whether a power of the RF signal exceeds a predetermined threshold; and
limiting amplification of the main amplifier to the Class-AB amplifier until a determination that the RF signal exceeds the predetermined threshold and then amplifying the first RF signal using the Class-AB amplifier and the Class-C amplifier.

22. The method of claim 21, further comprising providing amplification by the Class-C amplifier and the auxiliary amplifier in response to a determination that the power of the RF signal exceeds 6 dB power backoff (PBO).

23. Radio integrated circuit (IC) circuitry, comprising:
a mixer configured to convert a baseband signal to a radio frequency (RF) signal;
a first and second amplifier configured to amplify the RF signal to generate an amplified RF signal, the first amplifier configured to transition from saturation mode to triode mode while the second amplifier transitions from the triode mode to the saturation mode, the first and second amplifiers biased to provide an average gate-drain capacitance that remains substantially constant as the first amplifier transitions from the saturation mode to the triode mode and the second biased amplifier transitions from the triode mode to the saturation mode; and
a bandpass filter configured to filter the amplified RF signal.

24. The radio IC circuitry of claim 23, wherein the first and second biased amplifiers are disposed in parallel such that inputs of the first and second biased amplifiers are coupled together and outputs of the first and second biased amplifiers are coupled together.

25. The radio IC circuitry of claim 23, wherein the first and second biased amplifiers are disposed in serial such that an input of the second biased amplifier is coupled to an output of the first biased amplifier.
